(19) United States
(12) Patent Application Publication
(10) Pub. No.: US 2021/0118912 A1
(43) Pub. Date: Apr. 22, 2021

(54) SEMICONDUCTOR PATTERNING

(71) Applicant: FLEXENABLE LIMITED, Cambridge (GB)

(72) Inventors: Jan JONGMAN, Cambridge (GB); Brian ASPLIN, Cambridge (GB)

(73) Assignee: FLEXENABLE LIMITED, Cambridge (GB)

(21) Appl. No.: 16/463,670

(22) PCT Filed: Nov. 28, 2017
(86) PCT No.: PCT/EP2017/080649

§ 371 Date: May 23, 2019

(30) Foreign Application Priority Data
Nov. 29, 2016 (GB) 1620223.6

(51) Int. Cl. H01L 27/12; H01L 27/28; H01L 51/00; H01L 51/05

(52) U.S. Cl. CPC H01L 27/127; H01L 27/283; H01L 51/0558; H01L 51/0018; H01L 27/1288

(57) ABSTRACT

A technique of producing a stack defining a plurality of TFTs including at least source/drain electrodes and addressing lines at a source/drain level, wherein the method comprises: forming a patterned source/drain level stack comprising at least a first layer over the support substrate and a second layer over the first layer, to define at least said source/drain electrodes and said addressing lines; depositing semiconductor channel material over at least said source/drain electrodes and said addressing lines; and patterning the layer of semiconductor channel material by a patterning process; wherein the material of the first layer is more resistant to removal by said patterning process than the material of said second layer.

Patterning of organic semiconductor layers is a technique used in the production of organic TFT arrays to reduce cross-talk between adjacent TFTs.

The production of organic TFT arrays typically uses inert metals such as gold for the conductor patterns including addressing lines and source/drain electrodes, but the inventors for the present application have also conducted research into using other conductor materials.

The inventors for the present application have noticed that breaks in addressing lines can occur in production, and have attributed the cause of the breaks to the organic semiconductor patterning process.

There is hereby provided a method of producing a stack defining a plurality of TFTs including at least source/drain electrodes and addressing lines at a source/drain level, wherein the method comprises: (i) forming a pattern of source/drain level material over a support substrate, to define at least said source/drain electrodes and said addressing lines; (ii) depositing semiconductor channel material over said pattern; (iii) patterning the layer of semiconductor channel material by removing said semiconducting channel material in regions outside said source/drain electrodes using a patterning process; wherein the method comprises, before step (ii), selectively protecting the source/drain level material of the pattern of source/drain level material in said regions against said patterning process, using a patterned layer of protective material.

According to one embodiment, the protective material in the patterned layer of protective material is substantially aligned to the source/drain level material in the pattern of source/drain level material in said regions outside said source/drain electrodes.

According to one embodiment, the semiconductor channel material in the patterned layer of semiconductor channel material overlaps the protective material in the patterned layer of protective material, in boundary regions where the source/drain level material extends under an edge portion of the semiconductor channel material after patterning of said layer of semiconductor channel material.

According to one embodiment, patterning of the layer of semiconductor channel material uses an etchant, and the patterned layer of protective material is more resistant to said etchant than the source/drain level material in said pattern of source/drain level material.

There is also hereby provided a method of producing a stack defining a plurality of TFTs including at least source/drain electrodes and addressing lines at a source/drain level, wherein the method comprises: forming a patterned source/drain level stack comprising at least a first layer over the support substrate and a second layer over the first layer, to define at least said source/drain electrodes and said addressing lines; depositing semiconductor channel material over at least said source/drain electrodes and said addressing lines; and patterning the layer of semiconductor channel material by a patterning process; wherein the material of the first layer is more resistant to removal by said patterning process than the material of said second layer.

According to one embodiment, the source/drain level stack comprises a third layer below the first layer, which third layer has a higher electrical conductivity than the first layer.

According to one embodiment, the material of the second layer and the material of the third layer have substantially equal charge injection properties.

According to one embodiment, both the material of the second layer and the material of the third layer have a work function greater than about 5.0 eV.

According to one embodiment, the patterning process uses an etchant, and the material of the first layer is more resistant to said etchant than at least the material of said second layer.

According to one embodiment, the source/drain level stack further comprises an adhesion promoting conductor layer below the third layer.

Embodiments of the invention are described in detail, hereunder, by way of example only, with reference to the accompanying drawings, in which:

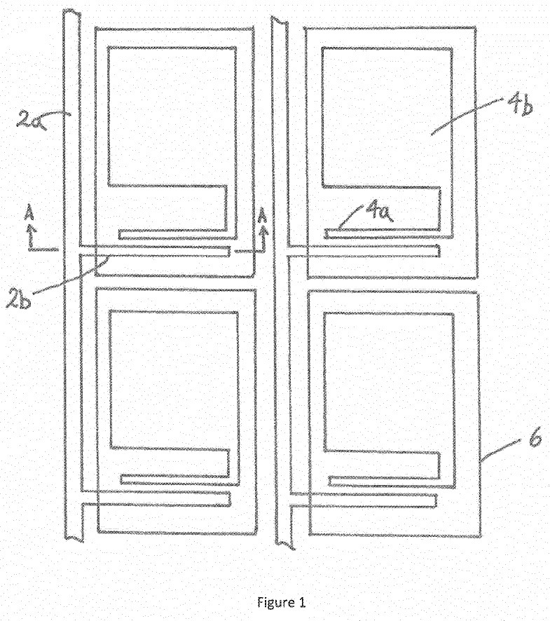

FIG. 1 illustrates one example of conductor and semiconductor patterns for an array of organic TFTs (OTFTs);

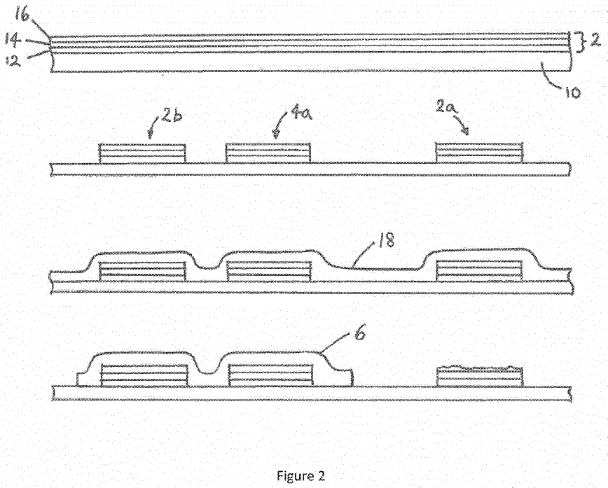

FIG. 2 illustrates a set of steps of a technique according to one example of an embodiment of the present invention; and

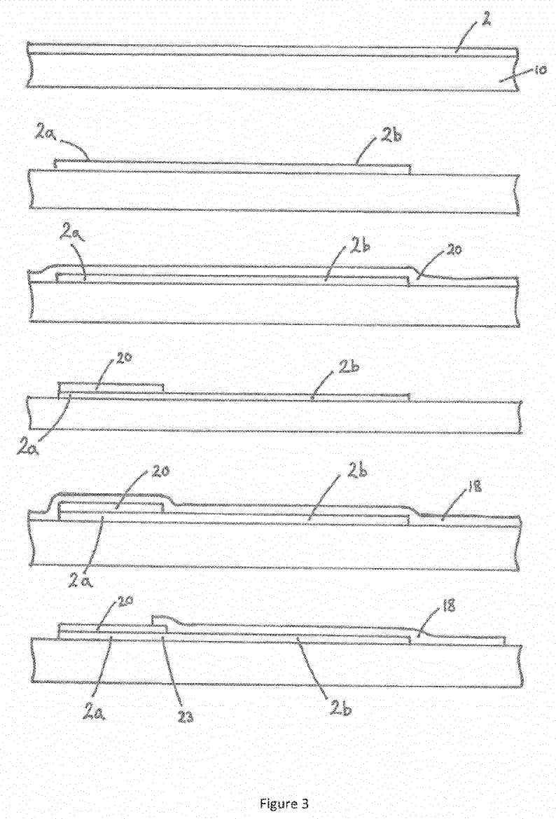

FIG. 3 illustrates a set of steps of a technique according to one example of another embodiment of the present invention.

Embodiments of the present invention are described below for the example of producing a TFT array for a display device, in which each pixel electrode is associated with a respective, single TFT within the TFT array. However, the same techniques are also applicable to, for example, TFT arrays for other kinds of devices such as sensors, and TFT arrays in which each pixel electrode is associated with a respective set of two or more TFTS within the TFT array.

FIG. 1 illustrates one example of a source-drain conductor level pattern and semiconductor pattern for a stack of conductor, semiconductor and insulator/dielectric layers defining an array of independently addressable TFTs. FIG. 1 only shows the conductors for four TFTs, but a typical OTFT array for e.g. a display device will typically comprise a dense array of over a million TFTs.

The conductor pattern may be produced by depositing one or more conductor materials over a substrate 10 (such as e.g. a plastic support film coated with an organic polymer planarization layer), and then patterning by e.g. photolithography. The conductor pattern defines an array of parallel conductors each defining the source conductors 2b and addressing line 2a for a respective column of TFTs. Each addressing line 2a is connected to a respective terminal of a driver chip (not shown). The conductor layer also defines drain conductors 4 for the TFTs. In the example illustrated in FIG. 1, the drain conductors comprise conductor fingers 4a in closest proximity to the source finger conductors 2b, and drain pads 4b connected to the drain conductor fingers 4a and serving as a base for a vertical interconnect (not shown) to a conductor higher in the stack such as a pixel electrode (not shown). The stack further includes: dielectric material deposited over the semiconductor pattern to provide the gate dielectric of the TFTs; a 2^{nd} conductor pattern over the gate dielectric, defining an array of gate lines each providing the gate conductors for a respective row of TFTs and connected to a respective terminal of a gate driver chip; insulator material deposited over the gate conductor pattern; and a 3^{rd} conductor pattern defining an array of pixel electrodes each connected to a drain pad 4b of a respective TFT by a respective vertical interconnect. However, these upper elements of the stack are not shown in the drawings for conciseness.

The stack may also include other intermediate layers such as e.g. an organic self-assembled monolayer (SAM) formed selectively on the conductor parts of the conductor pattern (i.e. not in regions between conductor parts within the conductor pattern) to improve the transfer of charge between the organic semiconductor and the source/drain conductors.

A layer of organic polymer semiconductor material (OSC) 18 is deposited by solution processing (such as spin-processing) over the whole area of the conductor pattern (i.e. including those areas where there is no conductor), and then patterned by dry etching to produce a semiconductor pattern defining islands 6 unconnected to each other within the semiconductor pattern.

With reference to FIG. 2, a technique according to one embodiment of the present invention involves forming the source/drain conductor pattern from a stack of layers comprising at least three layers: a first, silver/palladium alloy layer 12; a second, indium-tin oxide (ITO) layer 14; and a third, silver/palladium alloy layer 16. The stack may comprise additional conductor layers such as e.g. a bottom metal/alloy layer that serves to improve the adhesion of the conductor pattern to the surface of the underlying substrate 10, which may be an organic surface, such as the surface of an organic polymer planarization layer.

With reference to FIG. 2: the stack of conductor layers 2 is patterned by e.g. photolithography to define the conductor pattern; organic semiconductor material 18 is deposited over the whole of the conductor pattern; and then the organic semiconductor material is patterned by e.g. photolithography using a dry etchant.

This technique is found to result in less breaks in addressing lines, even when using relatively non-inert metals for the conductor pattern; and the technique facilitates the use of relatively non-inert conductor materials for the conductor pattern, such as silver alloys, which can be preferred from the point of view of reducing production costs.

As illustrated in the bottom part of FIG. 2, the inventors believe that the second, ITO layer 14 functions to preserve the integrity of the conductor pattern in those areas where the organic semiconductor is etched away. ITO is used for the middle layer 14 of the three-layer stack in the example described above, but there exist e.g. other conductive inorganic compounds that are resistant to the organic semiconductor etching process, and have the necessary level of electrical conductivity for whatever size of current is required through the organic semiconductor channels of the TFTs.

The addition of the third, silver/palladium alloy layer 16 over the ITO layer 14 is found to improve the performance of the OTFTs. This improvement is attributed to the relatively high work function of palladium, but there exist other materials that have high work functions (e.g. greater than about 5.0 eV). Furthermore, the third, silver/palladium layer 16 may be omitted where the second layer 14 has the necessary electronic properties for good transfer of charge to and from the organic semiconductor (via the above-mentioned organic self-assembled monolayer (SAM), if used).

In the example, described above, a silver/palladium alloy is used for the first layer, but there also exist other conductor materials that have equally good or better electrical conductivity to avoid excessive voltage drops along the addressing lines.

In the example described above, the same material is used for the first and third layers, but the materials of these two layers may also be different.

FIG. 3 illustrates a technique according to another embodiment of the present invention. FIG. 3 illustrates a series of steps for the example of the cross-section through A-A in FIG. 1. A layer of source/drain material 2 (which may comprise a stack of sub-layers) is formed over substrate 10, and patterned to form the conductor pattern illustrated in FIG. 1, comprising addressing lines 2a, source finger conductors 2b, drain finger conductors 4a and drain pads 4b. A layer of ITO 20 is deposited over all of the conductor pattern defining the source and drain conductors 2, 4, and the ITO layer is then patterned by a chemical etching technique that etches the ITO 20 without any substantial etching of the conductor material of the underlying conductor pattern. One example of a suitable chemical etching process uses hydrochloric acid as a chemical etchant. The mask used for patterning the ITO layer 20 is designed to selectively retain ITO 20 in regions that both (a) overlie conductor material in the conductor pattern and (b) from which the organic semiconductor (OSC) layer 18 is to be removed in a later step. This includes the conductor lines 2a connecting the source fingers 2b of respective columns of TFTs to respective driver terminals (not shown). The mask used to pattern the ITO is designed such that the ITO remaining after patterning of the ITO layer 20 substantially aligns with the conductor parts of the conductor pattern. This is illustrated in FIG. 3, where an edge of the ITO pattern substantially aligns with the left edge of the addressing line part 2a of the source conductor 2. In other words, substantially no ITO remains in regions between conductors of the conductor pattern, after patterning of the ITO layer 20.

A layer comprising organic polymer semiconductor (OSC) material 20 is formed over the whole area of the ITO pattern including both regions where no ITO remains after patterning and regions where ITO does remain after patterning. The OSC material is then patterned by photolithography using a dry etchant, to form islands 6 of OSC material, each island providing the semiconductor channel for a respective TFT, and unconnected to any other island within the patterned OSC layer.

As shown in FIG. 3, the masks used for patterning the ITO layer 20 and OSC layer 18 are designed together to result in some overlap of the ITO 20 and the OSC 18 in regions where conductor material of the conductor pattern extends between a region from which the organic semiconductor material 18 is to be retained to a region from which the organic semiconductor material is to be removed (e.g. part 23 of the source finger conductor 2b in FIG. 3), such that there can be no conductor parts of the conductor pattern that are both uncovered by ITO 20 and subject to OSC etching 18, whatever the degree of misalignment between the two masks within the expected unavoidable range of misalignment associated with the production process.

ITO is used in the example described above, but there exist other materials that are equally or more resistant to the OSC dry etching process used to pattern the organic polymer semiconductor layer.

The deposition of the organic semiconductor material may be preceded by a surface treatment step and/or deposition, selectively on the parts of the conductor pattern exposed by patterning of the ITO, of a self-assembled monolayer of organic material that facilitates the transfer of charge carriers between the inorganic metal conductor and the organic semiconductor.

In addition to any modifications explicitly mentioned above, it will be evident to a person skilled in the art that various other modifications of the described embodiments may be made within the scope of the invention.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features.

1. A method of producing a stack defining a plurality of TFTs including at least source/drain electrodes and addressing lines at a source/drain level, wherein the method comprises:
forming a patterned source/drain level stack comprising at least a first layer over the support substrate and a second layer over the first layer, to define at least said source/drain electrodes and said addressing lines;
depositing semiconductor channel material over at least said source/drain electrodes and said addressing lines; and
patterning the layer of semiconductor channel material by a patterning process; wherein the material of the first layer is more resistant to removal by said patterning process than the material of said second layer.

2. The method according to claim 1, wherein the source/drain level stack comprises a third layer below the first layer, which third layer has a higher electrical conductivity than the first layer.

3. The method according to claim 2, wherein the material of the second layer and the material of the third layer have substantially equal charge injection properties.

4. The method according to claim 2, wherein both the material of the second layer and the material of the third layer have a work function greater than about 5.0 eV.

5. The method according to claim 1, wherein the patterning process uses an etchant, and the material of the first layer is more resistant to said etchant than at least the material of said second layer.

6. The method according to claim 2, wherein the source/drain level stack further comprises an adhesion promoting conductor layer below the third layer.

7. A method of producing a stack defining a plurality of TFTs including at least source/drain electrodes and addressing lines at a source/drain level, wherein the method comprises:
(i) forming a pattern of source/drain level material over a support substrate, to define at least said source/drain electrodes and said addressing lines;
(ii) depositing semiconductor channel material over said pattern;
(iii) patterning the layer of semiconductor channel material by removing said semiconducting channel material in regions outside said source/drain electrodes using a patterning process;
wherein the method comprises, before step (ii), selectively protecting the source/drain level material of the pattern of source/drain level material in said regions against said patterning process, using a patterned layer of protective material.

8. The method according to claim 7, wherein the protective material in the patterned layer of protective material is substantially aligned to the source/drain level material in the pattern of source/drain level material in said regions outside said source/drain electrodes.

9. The method according to claim 8, wherein the semiconductor channel material in the patterned layer of semiconductor channel material overlaps the protective material in the patterned layer of protective material, in boundary regions where the source/drain level material extends under an edge portion of the semiconductor channel material after patterning of said layer of semiconductor channel material.

10. The method according to claim 7, wherein patterning of the layer of semiconductor channel material uses an etchant, and the patterned layer of protective material is more resistant to said etchant than the source/drain level material in said pattern of source/drain level material.
